(19) United States
(12) Patent Application Publication
(10) Pub. No.: US 2007/0030873 A1
(43) Pub. Date: Feb. 8, 2007

(54) Polarization control in VCSELs using photonics crystals

(75) Inventor: Hongyu Deng, Saratoga, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: Finisar Corporation

(21) Appl. No.: 11/196,571

(22) Filed: Aug. 3, 2005

(51) Int. Cl. H01S 5/00; H01S 3/08

(52) U.S. Cl. 372/50.11; 372/98

(57) ABSTRACT

An optical device including a polarization control photonic crystal. The optical device includes a vertical cavity surface emitting laser. The optical device further includes a lower mirror formed on a substrate. The optical device also includes an upper mirror. An active region is between the lower mirror and the upper mirror. Photons generated in the active region are reflected between the upper mirror and the lower mirror through the active region. An asymmetrical photonic crystal including cavities is optically coupled in the optical device such that one polarization of light is better reflected by the asymmetrical photonic crystal than a competing polarization of light.

### BACKGROUND

1. The Field of the Invention

The invention generally relates to polarization control in VCSELS. More specifically, the invention relates to using photonic crystals to control polarization in VCSELs.

2. Description of the Related Art

Some of the most commonly used light sources in optical communication systems are semiconductor lasers. Vertical cavity surface emitting lasers (VCSELs) are an example of semiconductor lasers and are used in optical communication systems for several reasons. VCSELs can be manufactured in large quantities due to their relatively small size and can often be tested at the wafer level. VCSELs typically have low threshold currents and can be modulated at high speeds. VCSELs also couple well with optical fibers.

A VCSEL typically requires a high reflectivity mirror system because in a VCSEL, the light resonates in a direction that is perpendicular to the pn-junction. The cavity or active region of a VCSEL is thus relatively short and a photon has little chance of stimulating the emission of an additional photon with a single pass through the active region. To increase the likelihood of stimulating the emission of photons, VCSELs require highly efficient mirror systems such that a photon can make multiple passes through the active region. The reflectivity requirement of VCSELs typically cannot be satisfied or achieved with metallic mirrors or cleaved semiconductor-to-air interface mirrors.

VCSELs thus employ Distributed Bragg Reflector (DBR) layers as mirrors. DBR layers are formed or grown using, for example, semiconductor or dielectric materials. DBR layers are grown or formed by alternating layers of materials of certain thickness and different refractive indices. The junctions between the DBR layers that are grown in this fashion cause light to be reflected. The amount of light reflected, however, by a single junction is relatively small and dependents on the variance between the relative refractive indices of the adjoining materials. For this reason, a relatively large number of DBR layers are formed in a VCSEL to achieve high reflectivity. VCSELs, for example, often have on the order of 20, 50, and up to 100 DBR layers in order to achieve sufficient reflectivity. The large number of DBR layers also increases the electrical resistance of the VCSEL and may lead to problems with both heating during operation and the growth or formation of the layers.

One challenge that exists with the above mentioned devices relates to polarization of optical beams. For example, in communication circuits, if polarized light is emitted from a laser device, the light can be routed using various types of beam splitters and polarization selective filters. Additionally, un-polarized light reflected back into the laser cavity can cause feedback reverberation issues that affect the laser output.

For traditional edge-emitting lasers polarization is typically fixed by the inherent laser geometry. An isolator can be used that allows linearly polarized light to pass in only one direction, whereas the same light reflected back would be blocked by the isolator and therefore not reach back to the laser to cause unwanted optical perturbations. For VCSELs, however, such natural geometry to determine laser polarization does not exit. An isolator that works for laser emission without single fixed polarization would be significantly more costly.

### BRIEF SUMMARY

One embodiment described herein includes an optical device. The optical device includes a vertical cavity surface emitting laser. The optical device further includes a lower mirror formed on a substrate. The optical device also includes an upper mirror. An active region is between the lower mirror and the upper mirror. Photons generated in the active region are reflected between the upper mirror and the lower mirror through the active region. An asymmetrical photonic crystal including cavities is optically coupled in the optical device such that one polarization of light is better reflected by the asymmetrical photonic crystal than a competing polarization of light.

Another embodiment includes a method of manufacturing an optical device. The method includes forming a lower mirror on a substrate. An active region is formed on the lower mirror. An upper mirror is formed on the active region. The method further includes forming an asymmetrical photonic crystal that includes cavities. The asymmetrical photonic crystal is optically coupled in the optical device such that one polarization of light is better reflected by the asymmetrical photonic crystal than a competing polarization of light.

Yet another embodiment includes a method of generating an optical signal. The method includes injecting free carriers into an active region of a VCSEL. Photons are created when the free carriers recombine. The photons travel in a laser cavity. The photons are selectively reflected in the laser cavity using an asymmetrical photonic crystal such that photons of a selected polarization better reflected by the asymmetrical photonic crystal than competing polarizations. The method further includes emitting the photons of a selected polarization from the VCSEL

Advantageously, the embodiments summarized above allow for polarization pinning in VCSELs through the use of photonic crystals. This allows for optical devices to be constructed with lower threshold voltages and allows for the used of other external components to control reflections. Further, when used in communication circuits, VCSELs with pinned polarizations can be used with various beam splitters, and polarization dependant routing devices.

These and other advantages and features of the present invention will become more fully apparent from the following description and appended claims, or may be learned by the practice of the invention as set forth hereinafter.

### BRIEF DESCRIPTION OF THE SEVERAL VIEWS OF THE DRAWINGS

In order that the manner in which the above-recited and other advantages and features of the invention are obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIG. 1A is a perspective view of a photonic crystal or layer with a square periodic cavity structure;

FIG. 1B is a top view of a photonic crystal or layer that has a honeycomb periodic cavity structure;

FIG. 1C is a top view of a photonic crystal or layer that has a rhombic periodic cavity structure;

FIG. 2 illustrates a vertical cavity surface emitting laser where the mirror layers are formed from photonic crystals;

FIG. 3 illustrate a vertical cavity surface emitting laser where the mirror layers are formed from a combination of photonic crystals and distributed Bragg Reflector layers;

FIG. 4 illustrates an active region of a vertical cavity surface emitting laser, where the active region is bounded by one mirror layer that includes a photonic crystal on one side and by a mirror layer that includes both a photonic crystal and Distributed Bragg Reflector layers on the other side; and

FIG. 5 illustrates a VCSEL with an inherent asymmetry.

### DETAILED DESCRIPTION

An 850 nm VCSEL is typically constructed on a semiconductor wafer such as Gallium Arsenide (GaAs). The VCSEL includes a bottom mirror constructed on the semiconductor wafer. Typically, the bottom mirror includes a number of alternating high and low index of refraction layers. As light passes from a layer of one index of refraction to another, a portion of the light is reflected. By using a sufficient number of alternating layers, a high percentage of light can be reflected by the mirror.

An active region that includes a number of quantum wells is formed on the bottom mirror. The active region forms a PN junction sandwiched between the bottom mirror and a top mirror, which are often of opposite conductivity types (i.e. a p-type mirror and an n-type mirror). Free carriers in the form of holes and electrons are injected into the quantum wells when the PN junction is forward biased by an electrical current. At a sufficiently high bias current (i.e. the threshold current) the injected minority carriers form a population inversion (i.e. a higher concentration of free carriers in the conduction band than electrons in the valance band) in the quantum wells that produces optical gain. Optical gain occurs when photons in the active region cause electrons to move from the conduction band to the valance band which produces additional photons. When the optical gain is equal to the loss in the two mirrors, laser oscillation occurs. The free carrier electrons in the conduction band quantum well are stimulated by photons to recombine with free carrier holes in the valence band quantum well. This process results in the stimulated emission of photons, i.e. coherent light.

The active region may also include an oxide aperture formed using one or more oxide layers formed in the top and/or bottom mirrors near the active layer. The oxide aperture serves both to form an optical cavity and to direct the bias current through the central region of the cavity that is formed.

A top mirror is formed on the active region. The top mirror is similar to the bottom mirror in that it generally comprises a number of layers that alternate between a high index of refraction and a lower index of refraction. Generally, the top mirror has fewer mirror periods of alternating high index and low index of refraction layers, to enhance light emission from the top of the VCSEL.

Illustratively, the laser functions when a current is passed through the PN junction to inject free carriers into the active region. Recombination of the injected free carriers from the conduction band quantum wells to the valence band quantum wells results in photons that begin to travel in the laser cavity defined by the mirrors. The mirrors reflect the photons back and forth. When the bias current is sufficient to produce a population inversion between the quantum well states at the wavelength supported by the cavity optical gain is produced in the quantum wells. When the optical gain is equal to the cavity loss laser oscillation occurs and the laser is said to be at threshold bias and the VCSEL begins to ‘lase’ as the optically coherent photons are emitted from the top of the VCSEL.

The VCSEL is generally formed as a semiconductor diode. A diode is formed from a pn junction that includes a p-type material and an n-type material. In this example, p-type materials are semiconductor materials, such as Gallium Arsenide (GaAs) doped with a material such as carbon that causes free holes, or positive charge carriers to be formed in the semiconductor material. N-type materials are semiconductor materials such as GaAs doped with a material such as silicon to cause free electrons, or negative charge carriers, to be formed in the semiconductor material. Generally, the top mirror is doped with p-type dopants where the bottom mirror is doped with n-type dopants to allow for current flow to inject minority carrier electrons and holes into the active region.

One issue that arises with VCSELs relates to polarization controls. Using polarization control helps to control feedback effects caused by portions of emitted laser light being reflected back into the laser. These reflections cause reverberations and affect the laser output.

One embodiment uses photonic crystals with asymmetries to pin polarization in a VCSEL. In a most basic example, a photonic crystal where lateral spacing in one direction is greater than lateral spacing in an orthogonal direction, such is in an asymmetric rectangle shape, may be used to pin polarization in a VCSEL. Other asymmetries may be used as well, such as asymmetries that form somewhat oval patterns, such as an asymmetrical octagon or honeycomb shape. The photonic crystal with an asymmetrical structure may be incorporated as part of, or as a replacement to, a DBR mirror of the VCSEL structure. Specifically, the asymmetries serve to be reflective to one polarization of light while being less or non-reflective to an orthogonal polarization of light. By being more reflective to one polarization, that polarization is promoted while competing polarizations are inhibited. The VCSEL may have a lower threshold current for the polarization that is reflected by the photonic crystals than competing polarizations. This may be use to reduce or completely eliminate the competing polarizations.

In one illustrative example, a method of generating an optical signal includes injecting free carriers into an active region of a VCSEL. As described above, this creates photons when the free carriers recombine. The photons travel in a laser cavity. The photons are selectively reflected in the laser cavity using an asymmetrical photonic crystal. Photons of a selected polarization are better reflected by the asymmetrical photonic crystal than photons of competing polarizations. The photons of the selected polarization are emitted from the VCSEL.

Asymmetrical photonic crystals exhibit different optical thicknesses for different polarizations of light. Light is largely reflected (about 30%) by materials that have an optical wavelength of nλ/2 where n is an integer. Additionally, light is largely not reflected when materials have an optical wavelength of nλ/4 where n is an odd integer. High reflectivity lowers the threshold current required for lasing. Thus, if a polarization to be promoted sees asymmetrical photonic crystal as an integral multiple of λ/2 and a polarization to be inhibited sees the asymmetrical photonic crystal as an odd integral multiple of λ/4, the polarization to be promoted will have a lower threshold current, while the polarization to be inhibited will have a higher threshold current. If the threshold difference between the polarization to be promoted and the polarization to be inhibited is great enough, a threshold current can be used to bias the VCSEL such that the polarization to be promoted is emitted while there is not a sufficient amount of threshold current to allow the polarization to be inhibited to be emitted. The asymmetrical photonic crystal on a VCSEL surface can therefore be fabricated such that a dominant polarization caused by the asymmetries in the VCSEL can be promoted through the use of asymmetrical photonic crystal while the subservient polarization is inhibited or completely blocked through the use of the asymmetrical photonic crystal.

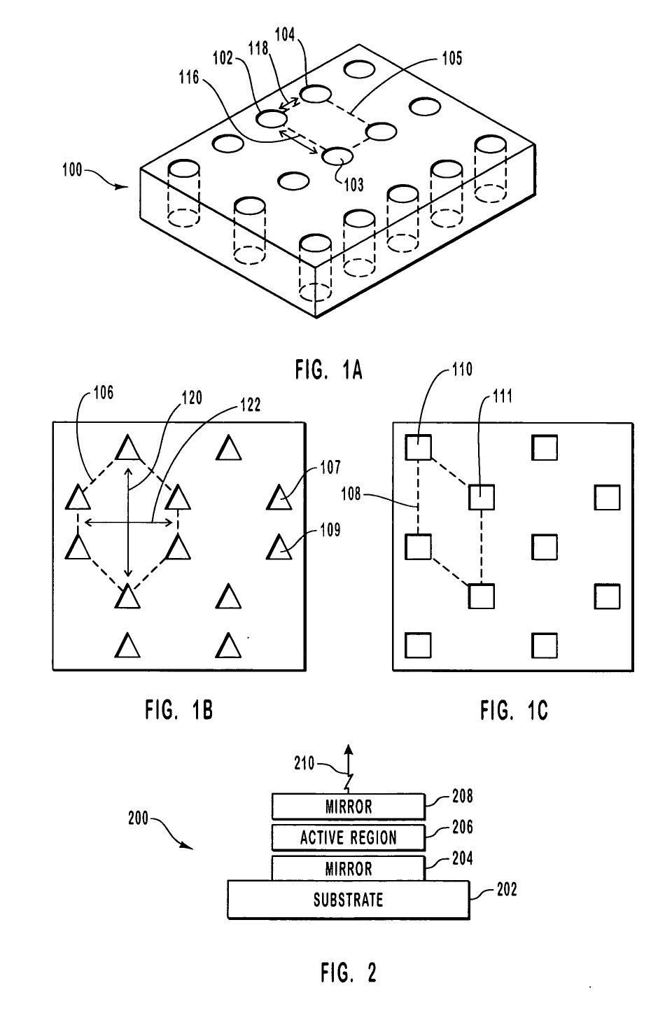

A photonic crystal is a material that has a cavity structure that is related to the wavelengths emitted by the VCSEL. FIG. 1A illustrates an exemplary photonic crystal or layer. A plurality of cavities are formed or structured in the photonic crystal 100. The cavities may be periodic in nature. Cavities 102 and 104 are examples of the cavities that are thus formed in the photonic crystal 100. Each cavity typically passes through the photonic crystal 100. This causes the photonic crystal 100 to have a perforated quality in this example. It is possible for the cavity structure to be formed such that the photonic crystal 100 is not perforated by cavities. In another example, the cavities may extend into other layers of the VCSEL. In other words, the cavities may extend into portions of a VCSEL in addition to the photonic crystal. The cavities are formed or placed in the photonic crystal 100 using an appropriate cavity structure that can vary according to the desired wavelength. The distance between cavities in the cavity structure may be related to the wavelengths of laser light that are generated by the VCSEL. In one example, the photonic crystal enables VCSELs to generate polarized light.

The polarization of light emitted by a VCSEL can be altered by changing characteristics or attributes of the photonic crystal. Characteristics or attributes than can be changed such that a VCSEL emits a particular polarization include, but are not limited to, the cavity structure, the shape of the cavities, the angle of the cavities with respect to the surface of the photonic crystal, the depth of the cavities, the material from OZ which the photonic crystal is formed, the thickness of the photonic crystal, and the like or any combination thereof.

As previously stated, the cavities that are formed in a photonic crystal may be periodic in nature or repeating. Examples of the periodic structure of the cavities in the photonic crystal 100 is thus illustrated in FIGS. 1A, 1B and 1C. FIG. 1A illustrates cavities that are formed using a rectangular cavity structure as illustrated by the dashed line 105. The cavities 102 and 103 in the photonic crystal 100 are located a first distance 116 in a first direction. The cavities 102 and 104 are a second distance 118 in a second direction. The first direction 116 is greater than the second direction 118 creating the previously referred to asymmetry.

FIG. 1B illustrates cavities that are formed using an asymetrical honeycomb cavity structure shown by the dashed line 106. In the example shown, the cavities are formed in the photonic crystal such that an asymmetrical shaped pattern is formed with a major axis 120 and a minor axis 122. The major axis 120 is greater in length than the minor axis 122. This creates an asymmetry that may be used to facilitate emissions from the VCSEL in one direction while inhibiting emissions in an orthogonal direction.

FIG. 1C illustrates cavities that are formed using an asymmetrical rhombic cavity structure shown by the dashed line 108. The present invention is not limited to these repeating structures but extends to other periodic cavity structures or other geometric cavity structures.

Cavities are not limited in shape either. The cavities 102 and 104 shown FIG. 1A are substantially circular in shape and form a circular column through the photonic crystal. The cavities 107 and 109 are substantially triangular in shape and form a substantially triangular column through the photonic crystal 100. The cavities 110 and 111 are substantially square in shape and form a substantially square column through the photonic crystal 100. While in the Figures illustrated, the shapes may be shown with hard edges and corners, those of skill in the art recognize that etching and other processes rarely resulting in features that are exactly square or with hard edges. Thus, when substantially square or triangular or other similar language is used herein, such language allows for rounded corners and edges as often occur in manufacturing processes.

The periodic cavity structure can be combined with any cavity shape and the present invention contemplates photonic crystals or layers whose cavities are of different shapes. In addition, the cavities may not pass completely through the photonic crystal, but may form a dimpled surface. Alternatively, the cavities may have a depth that extends into other layers of the VCSEL.

FIG. 2 is a block diagram that illustrates generally the structure of a VCSEL in accordance with the present invention. The VCSEL 200 is formed on a substrate 202. In some cases, the light exits the VCSEL through the substrate 202, which is often transparent to the laser light. Usually, one side of the VCSEL 200 is blocked to laser light such that light is only emitted from one side of the VCSEL. A lower mirror layer 204 is formed or grown on the substrate 202. An active region 206 is formed or grown on the mirror layer 204. On the active region 206, an upper mirror layer 208 is grown or formed. As the mirror layers 204 and 208 repeatedly reflect light or photons through the active region 206, the laser light 210 is ultimately generated and exits the VCSEL 200.

The active region 206 is typically formed from a semiconductor material. The mirror layers 204 and 208 can be formed from or include photonic crystals or layers. The photonic crystals provide the reflectivity required by the VCSEL 200 and are not as difficult to grow as the multiple DBR layers previously discussed. This makes VCSELs easier to fabricate and reduces cost. As explained previously, by using an asymmetrical photonic crystal, the reflectivity of one polarization is enhanced while the reflection of a competing polarization is inhibited.

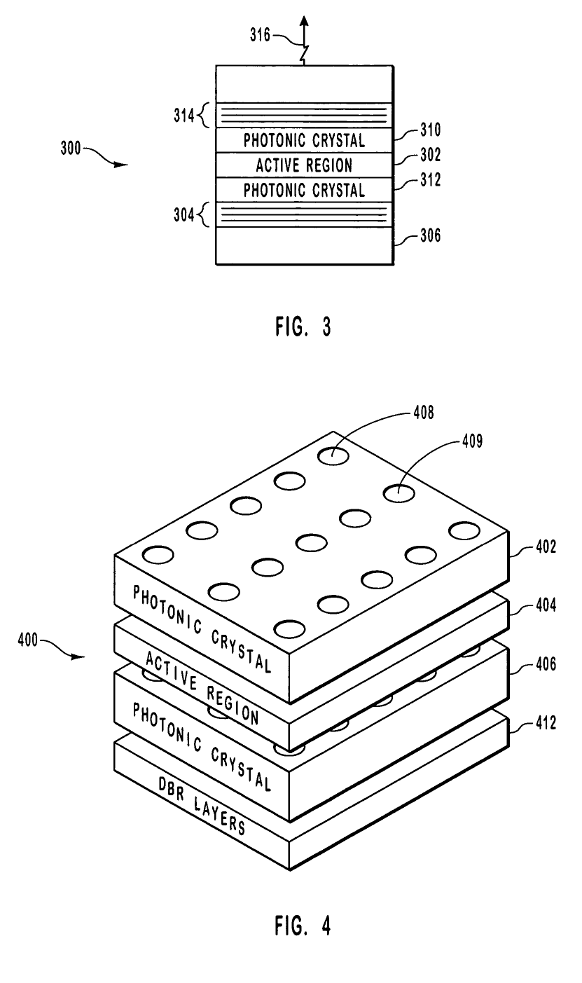

FIG. 3 illustrates another example of a VCSEL 300 that incorporates asymmetric photonic crystals as part of the mirror layers. In this example, the active region 302 is bounded by a photonic crystal 312 and a photonic crystal 310. The VCSEL 300 also utilizes DBR layers 304 and 314 as part of the mirror layers. The upper mirror layer thus includes the DBR layers 314 and the photonic crystal 310 while the lower mirror layer includes the DBR layers 304 and the photonic crystal 312. When photonic crystals are included as part of the mirror layers, the number of DBR layers can be reduced. The orientation or location of the photonic crystals with respect to the DBR layers can also be changed. In another embodiment, for example, the active region 302 is bounded by the DBR layers which, in turn, are bounded by the photonic crystals. When the photonic crystals 310 and 312 are formed next to the active region 302, the photonic crystals 310 and 312 and the active region 302 may be lattice matched to prevent stresses in the VCSEL structure.

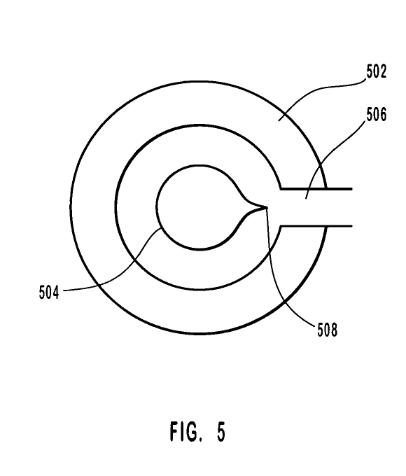

FIG. 4 is a perspective view of a VCSEL that uses photonic crystals or layers as mirrors. In this example, the VCSEL 400 includes an active region 404 that is bounded by a photonic crystal 402 and a photonic crystal 406. The photonic crystal 406 is formed on the DBR layers 412. In this example, both the photonic crystal 402 and the photonic crystal 406 have the same periodic cavity structure. The photonic crystal 402 and the photonic crystal 406 have a square cavity structure and the cavities have a circular shape as shown by the cavities 408 and 409.

The photonic crystals 402 and 406, however, are not required to have the same periodic cavity structure. The periodic structure of the cavities selected for the photonic crystal 406 may be affected, for example, by the DBR layers 412. The periodic structure of the cavities on the photonic crystals may also be influenced by the material used to form the photonic crystals. When the cavities of the photonic crystals 402 and 406 are first formed, they typically contain air. However, the present invention contemplates filling the cavities with another material.

In implementing asymmetric photonic crystals to pin polarization, the design of the asymmetric photonic crystal should take into account other asymmetries that may inherently exist in the VCSEL and intentional asymmetries in the VCSEL. For example, and referring to FIG. 5, a VCSEL 500 may be designed with a trench 502. The trench 502 is used in an oxidation stage to oxidize portions of the VCSEL 500 mesa structure to form the aperture 504. The aperture 504 acts to direct current through the VCSEL and as an optical aperture that controls how light is emitted from the VCSEL 500. In the example shown, a spoke 506 remains from the process used to form the trench 502. The spoke 506 is used to provide mechanical stability to the VCSEL 500. The aperture 504 is formed through an oxidation process such as by using an oxidizing agent in the trench 502. The trench 502 is asymmetrical due to the presence of the spoke 506. When oxidation occurs to form the aperture 504, a cusp 508 results which acts as an asymmetry in the aperture 504. This asymmetry will cause the VCSEL to favor one polarization of light over an orthogonal polarization. Each asymmetry in a VCSEL will tend to favor a polarization. Multiple asymmetries may compete with respect to which polarization is eventually emitted from the VCSEL. However, by designing an asymmetrical photonic crystal with the inherent and designed asymmetries already present in the VCSEL in mind, the asymmetry of the photonic crystal and other asymmetries may complement one another to favor a particular polarization.

One benefit of having a VCSEL with a polarized emitted light is the ability to prevent back reflections of light from affecting the VCSEL output. In one embodiment, this can be accomplished by using a quarter waveplate. The quarter waveplate can be positioned in an optical device such that light emitted from the VCSEL passes through the quarter waveplate. This causes the light emitted from the VCSEL to be changed from a linearly polarized light to a circularly polarized light. Any circularly polarized light reflected back into the VCSEL will be changed to linearly polarized light again, but rotated 90 degrees relative to the initial emission. The reflected light re-entering the laser cavity will be of an orthogonal polarization and thus will have a much reduced effect on emissions of the VCSEL when it enters into the laser cavity. In other words, by optically coupling the quarter waveplate to the VCSEL, the quarter waveplate can reduce harmful effects of light being reflected back into the optical device.

The photonic crystals can be formed, for example, from GaAs, AlGaAs, InGaAs, InP, GaInAsP, AlGaInAs, InGaAsN, InGaAsSb, and the like. The photonic crystals can also be formed from dielectric materials that can be deposited in a thin film. The material used to fill the cavities also extends to similar materials. The resonance frequency of the photonic crystal can be altered or changed if the refractive index of the material used to form the photonic crystal and/or fill the cavities is tunable.

In another example of the present invention, only one photonic crystal is provided as one of the other mirror layers. The other mirror layer is formed, for example, using DBR layers. In another example of the present invention, more than one photonic crystal is used. The addition of more photonic crystals extends the bandwidth of the VCSEL. More specifically, the upper and/or the lower mirror layer may include more than one photonic crystal. Each photonic crystal may be formed from a different material and each photonic crystal may have a different cavity structure. Other attributes of the photonic crystals, described above, may be independent of other photonic crystals in the VCSEL.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. An optical device including a vertical cavity surface emitting laser, the optical device comprising:
a lower mirror formed on a substrate;
an upper mirror;
an active region between the lower mirror and the upper mirror, wherein photons generated in the active region are reflected between the upper mirror and the lower mirror through the active region; and
an asymmetrical photonic crystal comprising cavities and optically coupled in the optical device to selectively reflect one polarization of light better than a competing polarization of light.

2. The optical device of claim 1, wherein the cavities form a substantially rectangular shape.

3. The optical device of claim 1, wherein the cavities are substantially periodic.

4. The optical device of claim 1, wherein the cavities are substantially circular.

5. The optical device of claim 1, wherein the cavities extend into portions of the optical device in addition to the photonic crystal.

6. The optical device of claim 1, further comprising a quarter waveplate optically coupled to light emitted from the optical device, the quarter waveplate being configured to reduce harmful effects of light being reflected back into the optical device.

7. The optical device of claim 1, wherein the asymmetrical photonic crystal forms a portion of the upper mirror.

8. The optical device of claim 1, wherein the asymmetrical photonic crystal forms a portion of the lower mirror.

9. The optical device of claim 1, wherein the asymmetrical photonic crystal is designed to complement other asymmetries in the optical device to promote polarized optical emissions from the optical device.

10. The optical device of claim 1, wherein the asymmetrical photonic crystal is coupled to the active region.

11. The optical device of claim 10, wherein the asymmetrical photonic crystal is lattice matched to the active region.

12. The optical device of claim 1, wherein the upper mirror is formed from a p-type semiconductor distributed Bragg reflector and the lower mirror is formed from a n-type semiconductor distributed Bragg reflector.

13. The optical device of claim 1, wherein the upper mirror and lower mirror are dielectric mirrors.

14. The optical device of claim 1, wherein the asymmetrical photonic crystal has an optical thickness of about nλ/2 where n is an integer for the one polarization of light that is better reflected.

15. A method of manufacturing an optical device comprising:
forming a lower mirror on a substrate;
forming an active region on the lower mirror;
forming an upper mirror on the active region; and
forming an asymmetrical photonic crystal comprising cavities and optically coupled in the optical device to selectively reflect one polarization of light better than a competing polarization of light.

16. A method of generating an optical signal comprising:
injecting free carriers into an active region of a VCSEL so as to create photons when the free carriers recombine, wherein the photons travel in a laser cavity;
selectively reflecting the photons in the laser cavity using an asymmetrical photonic crystal such that photons of a selected polarization are better reflected by the asymmetrical photonic crystal than competing reflections; and
emitting the photons of a selected polarization from the VCSEL.
